(19) United States
(12) Patent Application Publication
(10) Pub. No.: US 2012/0162874 A1
(43) Pub. Date: Jun. 28, 2012

(54) DISPLAY DEVICE

(75) Inventors: Takayuki Ito, Tokyo (JP); Mamoru Abe, Kanagawa (JP); Shintaro Miyatani, Tokyo (JP); Isamu Noguchi, Saitama (JP)

(73) Assignee: Sony Corporation, Tokyo (JP)

(21) Appl. No.: 13/298,820

(22) Filed: Nov. 17, 2011

(30) Foreign Application Priority Data
Dec. 28, 2010 (JP) 2010-293690

(51) Int. Cl. H05K 5/00

(52) U.S. Cl. 361/679.01

(57) ABSTRACT

A display device includes an outer case including a frame-shaped cabinet having receiving portions on the inner circumferential portion thereof such that a portion of the inner circumferential surface functions as a positioning surface; a display unit including a display portion in which a display is disposed and a holding base holding the display portion and where at least a portion of the outer circumferential portion of the holding base functions as a contact portion positioned further outside than the outermost circumferential surface of the display portion and the outermost circumferential surface of the display portion is formed as an aligning surface; and a pressing member that is disposed inside the outer case and positioned opposite to the display portion with the holding base therebetween.

### BACKGROUND

The present disclosure relates to the technical field of display devices. In detail, the present disclosure relates to a technical field of reducing the size of a product with favorable positioning accuracy by pressing a display unit with a portion of the display unit in contact with a portion of a cabinet, and performing positioning by an aligning surface of a display portion and a positioning surface of the cabinet.

Video cameras, still cameras, television receivers, and personal computers and the like are equipped with a display portion having a display, such as a liquid crystal panel or an organic electroluminescence panel.

In the display devices having the display portion, it is necessary to position and hold the display portion at a predetermined position with respect to the outer case, such that the display portion is disposed and held inside a frame-shaped cabinet of the outer case (see Japanese Unexamined Patent Application Publication No. 2009-265522).

In the display device disclosed in Japanese Unexamined Patent Application Publication No. 2009-265522, a flange-shaped protrusion extending inward from the cabinet is formed and a pressing member is disposed in the outer case. The display portion is held at a predetermined position, with the outer surface of the outer circumferential portion pressed by the frame-shaped protrusion and the inner surface pressed by the pressing member.

### SUMMARY

However, in the display device disclosed in Japanese Unexamined Patent Application Publication No. 2009-265522, the display portion is held with the outer surface of the outer circumferential portion pressed by the flange-shaped protrusion. Accordingly, the protrusion is positioned at the outer surface side of the display portion, that is, outside the display surface of the display portion, such that the thickness of the display device correspondingly increases and size reduction is difficult.

Further, since the outer circumferential portion of the display portion is covered by the flange-shaped protrusion, the display region for an image of the display portion correspondingly decreases and it is necessary to increase the size of the outer shape of the display portion in order to ensure a large display region. Therefore, it is also necessary to increase the outer shape of the display device, such that the display device increases in size.

There is another display device in which the display portion is fixed and held by an adhesion member, such as an adhesion tape, to the cabinet, but a space as larger as the thickness of the adhesion tape is necessary inside an outer case, such that the size is increased in the display device.

Meanwhile, when the holding position of the display portion deviates from the cabinet, the display portion is unstably held or the display portion inclines with respect to the outer case, such that visibility of the image displayed on the display surface may be deteriorated. Therefore, it is necessary to ensure favorable positioning accuracy of the display portion with respect to the cabinet.

It is desirable to provide a display device that is provided with favorable positioning accuracy of a display portion with respect to a cabinet and of which the size is reduced.

A display device according to an embodiment of the present disclosure includes: an outer case that includes a frame-shaped cabinet having receiving portions on the inner circumferential portion thereof such that a portion of the inner circumferential surface functions as a positioning surface; a display unit that includes a display portion in which a display is disposed and a holding base holding the display portion and where at least a portion of the outer circumferential portion of the holding base functions as a contact portion positioned further outside than the outermost circumferential surface of the display portion and the outermost circumferential surface of the display portion is formed as an aligning surface; and a pressing member that is disposed inside the outer case and positioned opposite to the display portion with the holding base therebetween, in which the holding base is pressed from the opposite side of the receiving portion of the cabinet by the pressing member, with the contact portion of the holding base in contact with the receiving portion of the cabinet such that the display unit is disposed with respect to the cabinet, and the aligning surface of the display portion and the positioning surface of the cabinet are positioned opposite to each other such that the display portion is positioned with respect to the cabinet.

Therefore, in the display device, the holding base is interposed by the receiving portion of the cabinet and the pressing member while the aligning surface of the display portion and the positioning surface of the cabinet is positioned opposite to each other.

In the display device, it is preferable that the display portion be disposed in the cabinet.

Since the display portion is disposed in the cabinet, the display portion does not protrude outside from the cabinet.

In the display device, it is preferable that a protective glass that protects the display be disposed at the display portion and the outer circumferential surface of the protective glass function as the aligning surface.

Since the protective glass that protects the display is disposed at the display portion and the outer circumferential surface of the protective glass functions as the aligning surface, the display portion is positioned with respect to the cabinet by the protective glass.

In the display device, it is preferable that a connecting substrate connected to the display portion be disposed at the display unit, the connecting substrate protrude outward from one edge of the holding base, and the contact portion be disposed at both sides of the connecting substrate at one edge of the holding base.

Since the connecting substrate connected to the display portion is disposed at the display unit and the contact portion is formed at both sides of the connecting substrate at one edge of the holding base, the position of the holding base to the cabinet is difficult to be changed by an external force applied to the connecting substrate.

In the display device, it is preferable that the pressing member be fixed inside the outer case.

Since the pressing member is fixed inside the outer case, the position of the pressing member to the outer case is not changed.

In the display device, it is preferable that the holding base be pressed by the pressing member through the cushion.

Since the holding base is pressed by the pressing member through the cushion, the holding base is pressed by the pressing member, with deviation of the assembled position absorbed by the cushion on the basis of the machining accuracy of the parts in the display device.

In the display device, it is preferable that the holding base be made of a metal material.

Since the holding base is made of a metal material, strength of the holding base pressed by the pressing member is high.

In the display device, it is preferable that the surface that is in contact with the receiving portion in the contact portion of the cabinet is blacked.

Since the surface that is in contact with the receiving portion in the contact portion of the cabinet be blacked, reflection from the contact portions is suppressed when light travels into the gap.

In the display device, it is preferable that the cabinet has a base portion made of a resin material and a reinforcing portion made of a metal material to reinforce the base portion.

Since the cabinet has a base portion made of a resin material and a reinforcing portion made of a metal material to reinforce the base portion, strength of the cabinet is high.

In the display device, it is preferable that the base portion and the reinforcing portion be integrally formed.

Since the base portion and the reinforcing portion are integrally formed, positional accuracy of the reinforcing portion to the base portion is high and the cabinet is implemented by one member.

In the display device, it is preferable that the holding base be made of a conductive material, the pressing member be made of a conductive material and connected to an earthed circuit, and a first connecting portion and a second connecting portion in which the holding base and the pressing member are partially connected, respectively, be formed at the reinforcing portion.

Since the holding base is made of a conductive material, the pressing member is made of a conductive material and connected to an earthed circuit, and a first connecting portion and a second connecting portion where the holding base and the pressing member are partially connected, respectively, are formed at the reinforcing portion, the reinforcing portion reinforces the cabinet and functions as a conductive path for the holding base.

The display device of the embodiment of the present disclosure includes: an outer case that includes a frame-shaped cabinet having receiving portions on the inner circumferential portion thereof such that a portion of the inner circumferential surface functions as a positioning surface; a display unit that includes a display portion in which a display is disposed and a holding base holding the display portion and where at least a portion of the outer circumferential portion of the holding base functions as a contact portion positioned further outside than the outermost circumferential surface of the display portion and the outermost circumferential surface of the display portion is formed as an aligning surface; and a pressing member that is disposed inside the outer case and positioned opposite to the display portion with the holding base therebetween, in which the holding base is pressed from the opposite side of the receiving portion of the cabinet by the pressing member, with the contact portion of the holding base in contact with the receiving portion of the cabinet such that the display unit is disposed with respect to the cabinet, and the aligning surface of the display portion and the positioning surface of the cabinet are positioned opposite to each other such that the display portion is positioned with respect to the cabinet.

Therefore, it is possible to reduce the size of the display device while ensuring high degree of positioning the display portion with respect to the cabinet.

According to the embodiment of the present disclosure, the display portion may be disposed in the cabinet.

Therefore, it may be possible to further reduce the size of the display device.

According to the embodiment of the present disclosure, a protective glass that protects the display may be disposed at the display portion and the outer circumferential surface of the protective glass functions as the aligning surface.

Therefore, since the protective glass that is the material of the protective glass has high machining accuracy and strength, it is possible to position the display portion accurately with respect to the cabinet.

According to the embodiment of the present disclosure, a connecting substrate connected to the display portion is disposed at the display unit, the connecting substrate protrudes from one edge of the holding base, and the contact portion is disposed at both sides of the connecting substrate at one edge of the holding base.

Therefore, the position of the holding base to the cabinet is not easily changed by an external force applied to the connecting substrate and it is possible to stably hold the display unit with the cabinet.

According to the embodiment of the present disclosure, the pressing member may be fixed inside the outer case.

Therefore, it is possible to improve stability of the display unit held with respect to the cabinet without changing the position of the pressing member with respect to the outer case.

According to the embodiment of the present disclosure, the holding base may be pressed by the pressing member through the cushion.

Therefore, the holding base is pressed by the pressing member, with deviation of the assembled position absorbed by the cushion on the basis of the machining accuracy of the parts in the display device, such that it is possible to stably hold the display unit with the cabinet regardless of the machining accuracy of the parts in the display device.

According to the embodiment of the present disclosure, the holding base may be made of a metal material.

Therefore, strength of the holding base is high, such that it is possible to further stably hold the display unit with the cabinet.

According to the embodiment of the present disclosure, surface that is in contact with the receiving portion in the contact portion of the cabinet may be blacked.

Therefore, when a gap is generated between the aligning surface and the positioning surface, reflection from the contact portions is suppressed when light travels into the gap, such that it is possible to improve visibility of the image displayed on the display portion.

According to the embodiment of the present disclosure, the cabinet may have a base portion made of a resin material and a reinforcing portion made of a metal material to reinforce the base portion.

Therefore, strength of the cabinet is high, such that it is possible to suppress deformation of the cabinet.

According to the embodiment of the present disclosure, the base portion and the reinforcing portion may be integrally formed.

Therefore, the positional accuracy of the reinforcing portion in respect to the display portion is high and the number of parts is reduced while it is possible to improve the strength of the cabinet.

According to the embodiment of the present disclosure, the holding base may be made of a conductive material, the pressing member may be made of a conductive material and connected to an earthed circuit, and a first connecting portion and a second connecting portion in which the holding base and the pressing member are partially connected, respectively, may be formed at the reinforcing portion.

Therefore, since the reinforcing portion reinforces the cabinet and functions as a conductive path for the holding base, it is possible to prevent damage by electrostatic discharge of the display unit while reducing the number of parts.

### BRIEF DESCRIPTION OF THE DRAWINGS

FIG. 1 is a perspective view of a display device with an opening/closing panel closed, which show the display device according to an embodiment of the present disclosure together with FIGS. 2 to 15.

FIG. 2 is a perspective view of the display device with the opening/closing panel open.

FIG. 3 is a perspective view of the display device seen in a direction different from FIGS. 1 and 2.

FIG. 4 is an exploded perspective view of the display device.

FIG. 5 is an exploded perspective view of the display device seen from a direction different from FIG. 4.

FIG. 6 is a perspective view of a cabinet.

FIG. 7 is a perspective view of a reinforcing portion of the cabinet.

FIG. 8 is an exploded perspective view of a display unit and the cabinet.

FIG. 9 is a perspective view when the display unit is disposed inside the cabinet.

FIG. 10 is an enlarged cross-sectional view when the display unit is disposed inside the cabinet.

FIG. 11 is an enlarged perspective view when the display unit is disposed inside the cabinet.

FIG. 12 is an enlarged perspective view when the display unit is disposed inside the cabinet, seen from a position different from FIG. 11.

FIG. 13 is an enlarged cross-sectional view when a holding base is connected to a first connecting portion of the reinforcing portion.

FIG. 14 is an enlarged cross-sectional view when a pressing member is connected to a second connecting portion of the reinforcing portion.

FIG. 15 is a block diagram of a display device.

### DETAILED DESCRIPTION OF EMBODIMENTS

Preferred embodiments for implementing a display device of the present disclosure are described hereafter with reference to the accompanying drawings.

The following preferred embodiments are implemented by applying a display device according to an embodiment of the present disclosure to a digital still camera.

However, the application range of the present disclosure is not limited to digital cameras and may be applied to imaging devices, such as a video camera, portable terminals, such as a mobile phone or a PDA (Personal Digital Assistant), information processing devices, such as a personal computer, and various display devices including a display part, such as a television receiver or a display monitor.

In the following description, the forward-backward, up-down, and left-right directions are defined on the basis of the view point of the photographer who takes a picture with a display device (digital still camera). Accordingly, an object is at the front and the photographer is at the rear.

Further, the forward-backward, up-down, and left-right directions are defined for the convenience of description and the directions are not limited in embodiments of the present disclosure.

### [Configuration of Display Device]

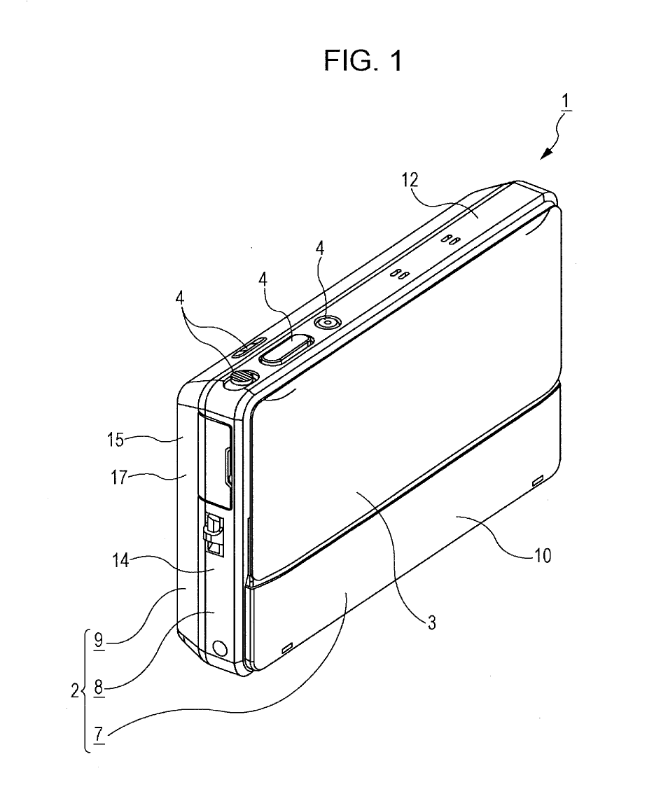

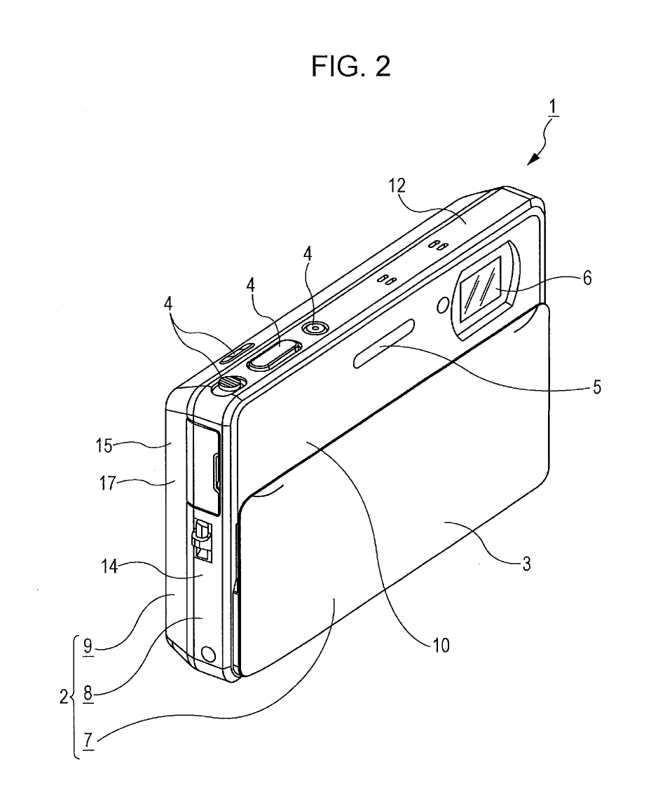

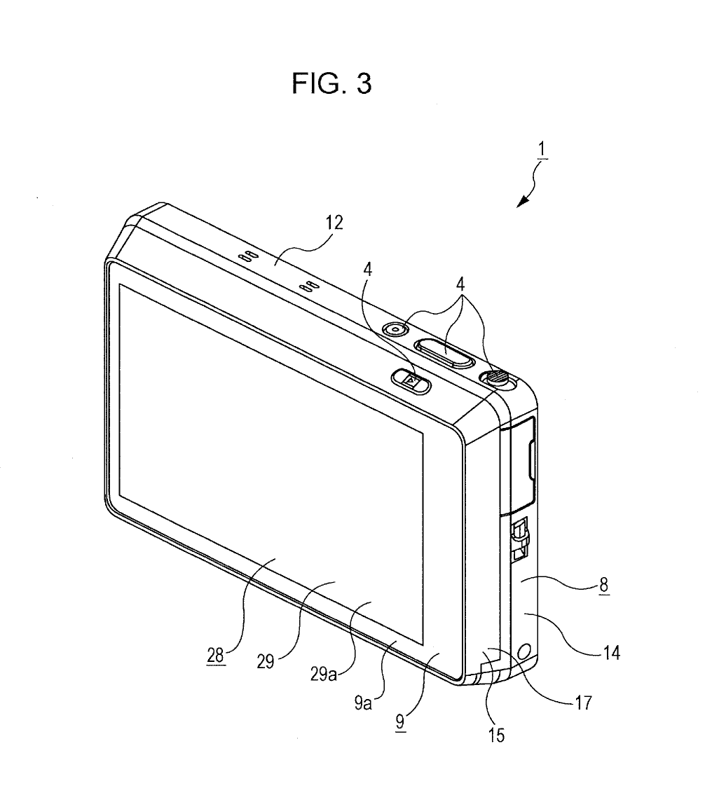

A display device (digital still camera) 1 includes a box-shaped outer case 2 and an opening/closing panel 3 that can slide in the up-down direction on the front surface of the outer case 2 (see FIGS. 1 to 3) and necessary components are disposed in the outer case 2.

Various operation parts 4, 4, . . . are disposed on the upper surface of the outer case 2. As the operation parts 4, 4, . . . , for example, a power button for supplying power, a shutter button operated during imaging, and a zoom button for zooming and the like are disposed.

A flash 5 that radiates sub-light in imaging and an imaging lens 6 that takes the image of an object are arranged at the left and right on the upper end of the front surface of the outer case 2. Various lenses or a lens group, which is not shown, are disposed along the light axis behind the imaging lens 6.

The flash 5 and the imaging lens 6 are opened/closed by the opening/closing panel 3 sliding in the up-down direction. An object can be photographed when the flash 5 and the imaging lens 6 are open by moving the opening/closing panel 3 down and the object may not be photographed when the flash 5 and the imaging lens 6 are closed by moving up the opening/closing panel 3 up.

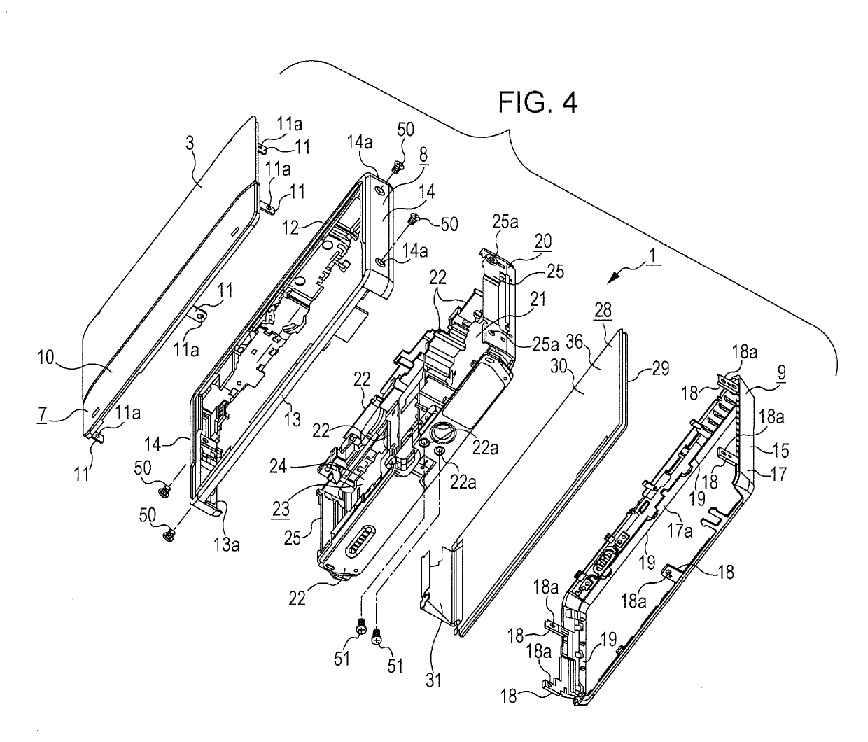

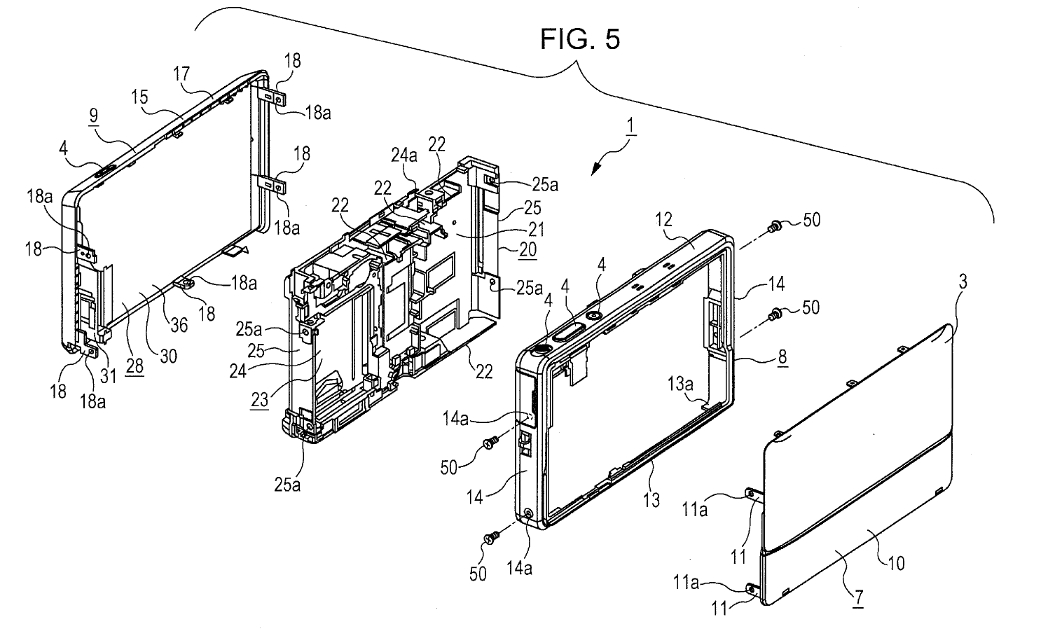

The outer case 2 includes a front panel 7, a frame 8, and a cabinet 9, and the front panel 7, the frame 8, and the cabinet 9 are sequentially combined in the front-back direction (see FIGS. 4 and 5).

The front panel 7 is composed of a plate-shaped panel portion 10 that is formed in a rectangular shape transverse in the front-back direction and attachment portions 11, 11, . . . protruding backward from the outer circumferential portion of the panel portion 10 and the opening/closing panel 3 is slidably supported on the front surface of the panel portion 10. Insertion holes 11a, 11a, . . . are formed through the attachment portions 11, 11, . . . , respectively.

The frame 8 is formed transversely in a substantially rectangular box shape and composed of a top portion 12, a bottom portion 13, and a pair of side portions 14 and 14. A notch 13a for disposing that is open to the back is formed at the bottom portion 13. Insertion holes 14a and 14a are formed up and down at a distance on the side portion 14.

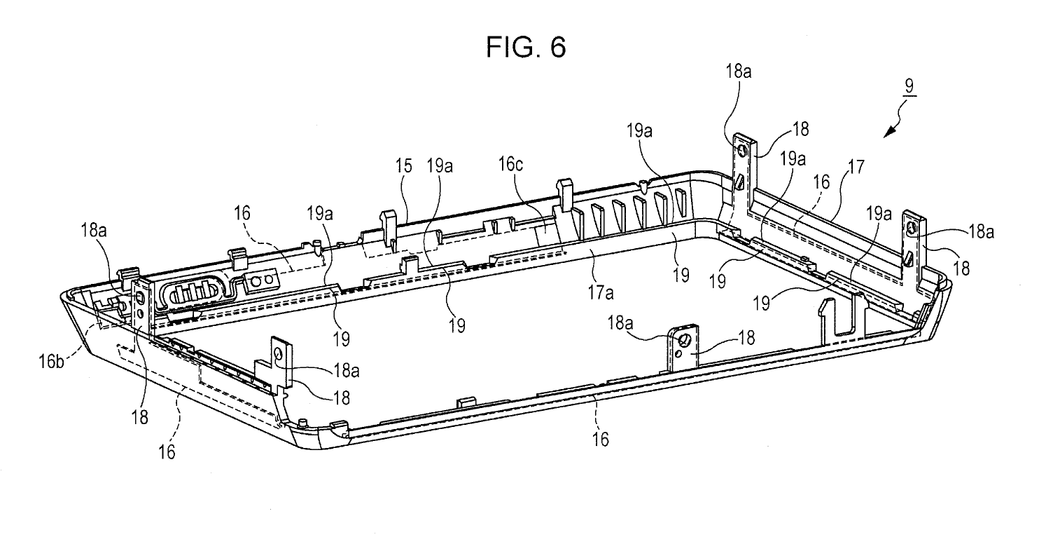

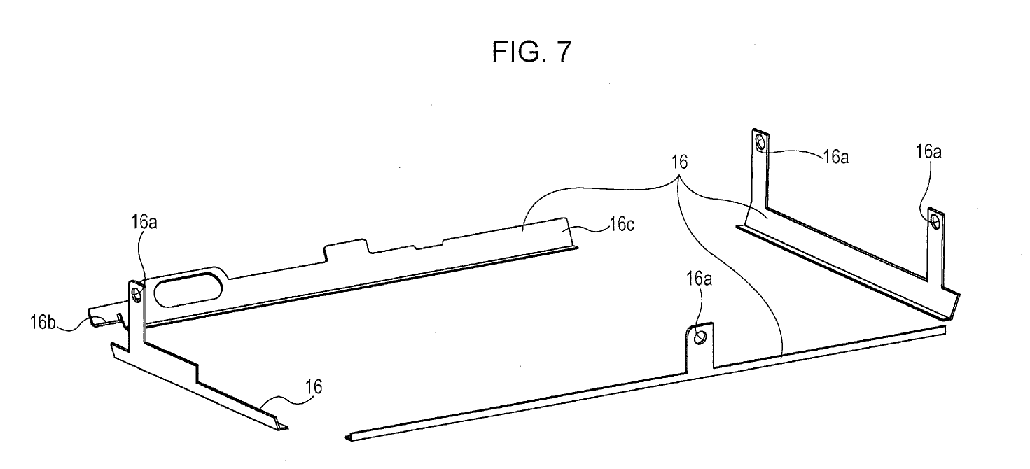

The cabinet 9 is composed of a base portion 15 made of a resin material in a substantially transversely rectangular frame shape and reinforcing portions 16, 16, . . . which are made of metal and reinforce the base portion 15 (see FIGS. 6 and 7). The base portion 15 and the reinforcing portions 16, 16, . . . are integrally formed by insert-forming for example.

The base portion 15 is the base of the cabinet 9 and has a frame 17 formed in a substantially rectangular frame shape and fastening portions 18, 18, . . . that protrude forward from the front edge of the frame 17.

The frame 17 inclines such that portion except for the rear end increases in size toward the front. Receiving portions 19, 19, . . . that circumferentially extend are disposed at the position close to the rear end of the inner circumferential portion of the frame 17. The receiving portions 19, 19, . . . protrude inward and have receiving surfaces 19a, 19a, . . . that are formed forward, respectively. The portion behind the receiving portions 19, 19, . . . in the inner circumferential surface of the frame 17 is formed horizontally or vertically as a positioning surface 17a.

Insertion holes 18a, 18a, . . . are formed through the fastening portions 18, 18, . . . , respectively.

The reinforcing portions 16, 16, . . . are partially embedded in four sides at the upper and lower portions and the left and right sides and the fastening portions 18, 18, . . . of the frame 17. Holes 16a, 16a, . . . are formed at position corresponding to the insertion holes 18a, 18a, respectively, at the portion embedded in the fastening portions 18, 18, . . . of the reinforcing portions 16, 16, . . . .

As described above, as the reinforcing portions 16, 16, . . . are formed at the frame 17 of the cabinet 9, the strength of the cabinet 9 increases and the cabinet 9 can be suppressed from deforming.

Further, as described above, as the base portion 15 and the reinforcing portions 16, 16, . . . are integrally formed, positional accuracy of the reinforcing portions 16, 16, . . . in respect to the base portion 15 is increased and the strength of the cabinet 9 can be improved with the number of parts reduced.

One reinforcing portion 16 is exposed to the inner circumferential surface of the base portion 15, at both longitudinal ends, and the exposed portions are disposed as a first connecting portion 16b and a second connecting portion 16c (see FIG. 5).

An inner frame 20 is disposed in the outer case 2 (see FIGS. 4 and 5). The inner frame 20 is made of, for example, a resin material and has a base plate portion 23 formed in a plate shape in the front-back direction and wall portions 22, 22, . . . that protrude forward from the base plate portion 23. Screw holes 22a and 22a are formed up and down at a distance, at the lowermost wall portion 22.

A holding member 23 is attached to the inner frame 20. The holding member 23 is formed by machining a plate-shaped metal material in a predetermined shape and has a holding surface 24 formed in the front-back direction, side portions 25 and 25 protruding forward from the left and right side edges of the holding surface 24, and a coupling portion 26 protruding forward from the lower edge of the holding surface 24.

A connecting surface 24a bending forward is formed at the upper edge of the holding surface 24.

Threaded-holes 25a and 25a are formed up and down at a distance at the side portion 25 and threaded-holes 26a and 26a are formed up and down at a distance at the coupling portion 26.

A cushion 27 is attached to the rear surface of the holding surface 24. The cushion 27 is made of a material having conductivity.

The inner frame 20 is combined with the frame 8 by the lowermost wall 22 inserted in the notch 13a for disposing at the bottom portion 13 of the frame 8.

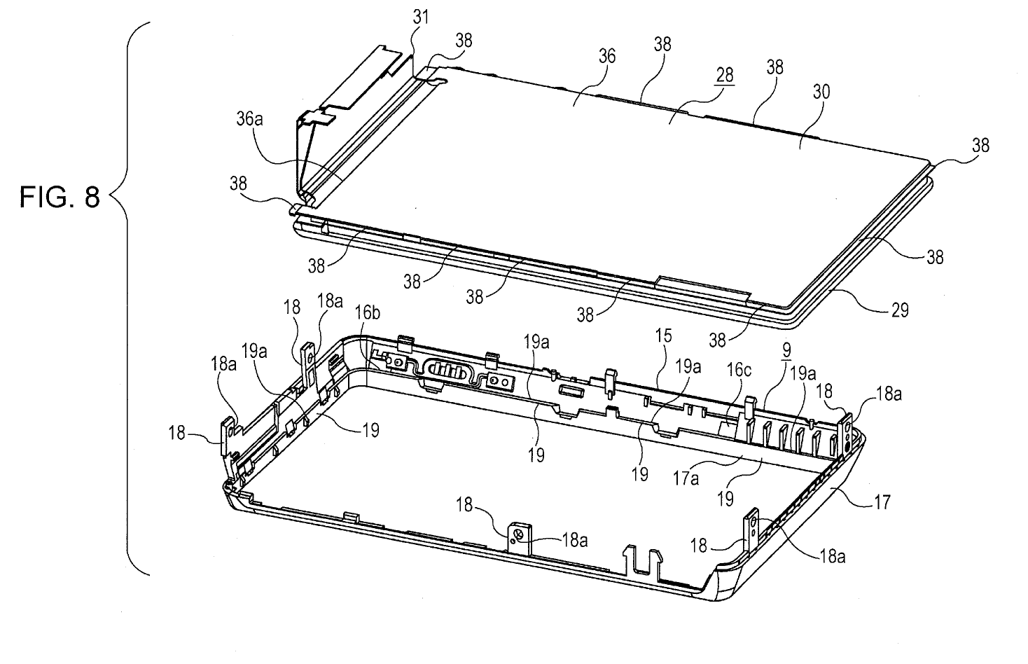

A display unit 28 is disposed behind the inner frame 20 and the display unit 28 is composed of a display portion 29, a holding base 30, and a connecting substrate 31 (see FIGS. 8 to 10).

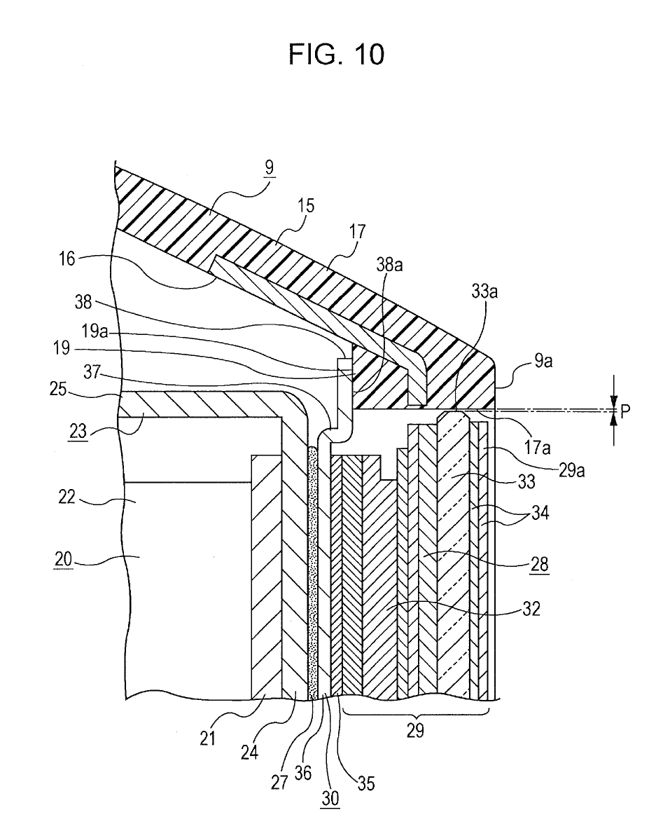

The display portion 29, as shown in FIG. 10, is achieved by stacking a display 32, such as an organic electroluminescence panel or a liquid crystal panel, a plate-shaped protective glass 33 disposed on the rear surface of the display 32, and anti-reflection sheets 34 and 34 attached to the rear surface of the protective glass 33.

The protective glass 33 has a function of protecting the display 32, the outermost shape of the display portion 29 increases, and the outer circumferential surface is formed as an aligning surface 33a.

The protective glass 33 is disposed such that the outer circumferential portion is positioned outside further than the outer circumferential surface of the display 32 and the outer circumferential surfaces of the anti-reflective sheets 34 and 34, and the aligning surface 33a is arranged horizontally or vertically. The outer shape of the protective glass 33 is formed slightly smaller than the shape of the positioning surface 17a of the cabinet 9.

The holding base 30 is made of a metal material and fixed to the front surface of the display portion 29, for example, by an adhesive 35. The holding base 30, as shown in FIG. 8, is composed of a base surface 36 formed in a substantially rectangular plate shape, connecting portions 37, 37, . . . that bend rearward from the outer circumferential portion of the base surface 36, and contact portions 38, 38, . . . that are connected to the outside of the connecting portions 37, 37, . . . , which are integrally formed.

A notch 36a for releasing which is open to a side is formed at one of the left and right sides of the base surface 36.

The contact portions 38, 38, . . . are formed in parallel with the base surface 36 and positioned behind the base surface 36. The contact portions 38, 38, . . . has the rear surfaces as contact surfaces 38a, 38a, . . . , respectively, and the contact surfaces 38a, 38a, . . . are blacked by coating, or the like. Further, the color applied to the contact surfaces 38a, 38a, . . . is not limited to black, a dark color may be possible, and for example, blue or brown may be applied to the contact portions 38a, 38a, . . . .

The outer edges of the contact portions 38, 38, . . . are positioned outside from the aligning surface 33a of the protective glass 33.

A connecting substrate 31 is connected at one end to the display portion 29. The connecting substrate 31 is a flexible printed wiring board and has the other end connected to a circuit board (not shown) disposed in the outer case 2. A driving circuit for driving the display 32 or a power supply circuit for supplying power is mounted on the circuit board.

The connecting substrate 31 protrudes rearward from the notch 36a for releasing formed at the holding base 30.

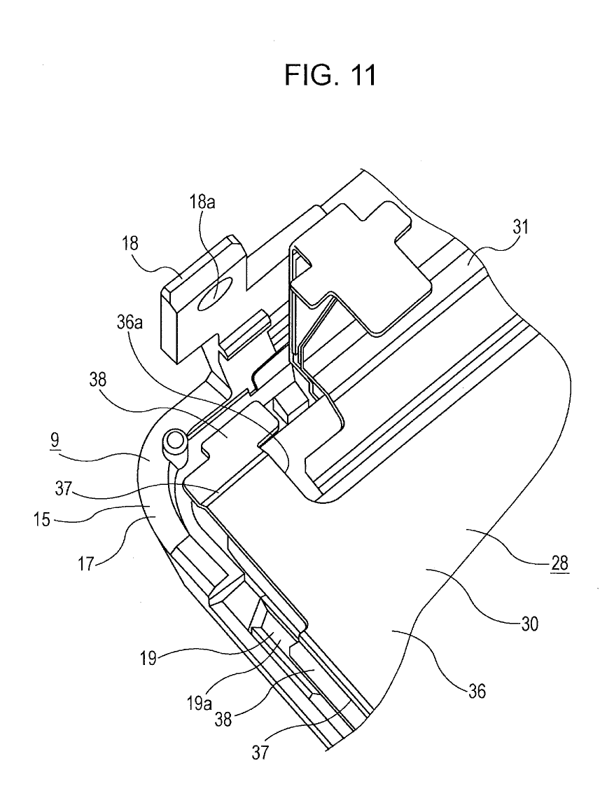

Two contact portions 38 and 38 in the contact portions 38, 38, . . . of the holding base 30 are disposed above and under the notch 36a for releasing of the base surface 36 (see FIGS. 8, 9, 11, and 12). Therefore, the contact portions 38 and 38 disposed above and under the notch 36a for releasing of the base surface 36 are positioned at both sides of the connecting substrate 31.

### [Assembly of Display Device]

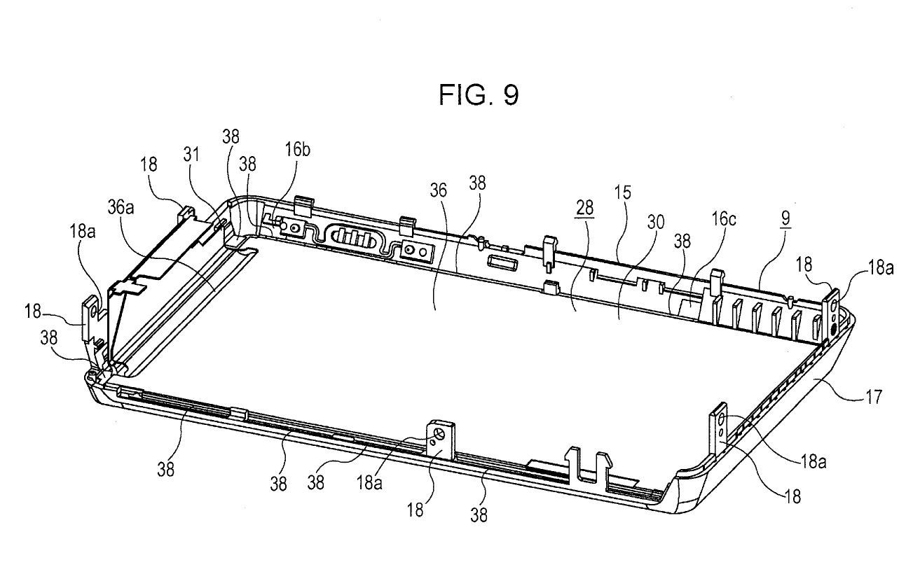

The display unit 28 is inserted into the cabinet 9 from the front (see FIGS. 8 and 9) and, as shown in FIG. 10, disposed such that the contact surfaces 38a, 38a, . . . of the contact portion 38, 38, . . . of the holding base 30 are in contact with the receiving surface 19a, 19a, . . . of the receiving portion 19, 19, . . . of the cabinet 9, respectively. As the contact surfaces 38a, 38a, . . . of the contact portion 38, 38, . . . are in contact with the receiving surface 19a, 19a, . . . of the receiving portion 19, 19, . . . , the display unit 28 is positioned in the front-back direction with respect to the cabinet 9.

In this state, the display portion 29 is inserted inside the positioning surface 17a such that the aligning surface 33a of the protective glass 33 and the positioning surface 17a of the cabinet 9 are opposite to each other, such that the display portion 29 is positioned in the up-down direction and the left-right direction with respect to the cabinet 9.

With the surfaces 38a, 38a, . . . of the contact portion 38, 38, . . . in contact with the receiving surface 19a, 19a, . . . of the receiving portion 19, 19, . . . and the display portion 29 inserted inside the positioning surface 17a, the rear surface 29a of the display portion 29 is in parallel with the rear surface 9a of the cabinet 9. Further, in this state, the rear surface 29a of the display portion 29 is positioned slightly ahead of the rear surface 9a of the cabinet 9, such that display portion 29 does not protrude forward from the cabinet 9, but the entire display portion 29 is disposed inside the cabinet 9.

With the surfaces 38a, 38a, . . . of the contact portion 38, 38, . . . in contact with the receiving surface 19a, 19a, . . . of the receiving portion 19, 19, . . . , the holding base 30 is pressed forward by the pressing member 23 through the cushion 27. Therefore, the holding base 30 is interposed forward and backward by the pressing member 23 and the receiving portions 19, 19, . . . and the display unit 28 is stably held in the outer case 2.

As described above, with the display unit 28 disposed inside the cabinet 9 and pressed by the pressing member 23 mounted on the inner frame 20, the frame 8 is assembled with the inner frame 20 from the front and the front panel 7 supporting the opening/closing panel 3 is assembled with the frame 8.

With the frame 8 assembled with the inner frame 20 and the front panel 7 assembled with the frame 8, as shown in FIGS. 4 and 5, attaching screws 50, 50, . . . are inserted into the insertion holes 14a, 14a, . . . formed at the side portions 14 and 14 of the frame 8. The attaching screws 50, 50, . . . are thread-fastened to the threaded-holes 25a, 25a, . . . formed at the side portions 25 and 25 of the pressing member 23, sequentially through the insertion holes 18a, 18a, . . . formed at the fastening portions 18, 18, . . . of the cabinet 9 and screw holes 11a, 11a, . . . formed at the attachment portions 11, 11, . . . of the front panel 7.

Further, with the frame 8 assembled with the inner frame 20 and the front panel 7 assembled with the frame 8, as shown in FIG. 4, screw members 51 and 51 are inserted into screw holes 22a and 22a formed at the wall 22 of the inner frame 20. One screw member 51 is inserted into the insertion hole 18a formed at the fastening portion 18 of the cabinet 9 and thread-fastened to one threaded-hole 26a formed at the fastening portion 26 of the pressing member 23. The other screw member 51 is inserted into the screw hole 11a formed at the fastening portion 11 of the front panel 7 and thread-fastened to the other threaded-hole 26a formed at the fastening portion 26 of the pressing member 23.

As described above, as the attaching screws 50, 50, . . . are thread-fastened to the threaded-holes 25a, 25a, . . . and the screw members 51 and 51 are thread-fastened to the threaded-holes 26a and 26a, the front panel 7, frame 8, inner frame 20, and cabinet 9 are combined, thereby achieving the display device 1. Therefore, the inner frame 20 is stably disposed in the outer case 2, the display unit 28 is stably pressed by the pressing member 23 mounted on the inner frame 20, and the display unit 28 is stably disposed inside the cabinet 9.

With the display device 1 implemented, the inner frame 20 and the holding member 23 are fixed with respect to the outer case 2 by the attaching screws 50, 50, . . . and the screw members 51 and 51.

### [Conductive State of Holding Base and Pressing Member]

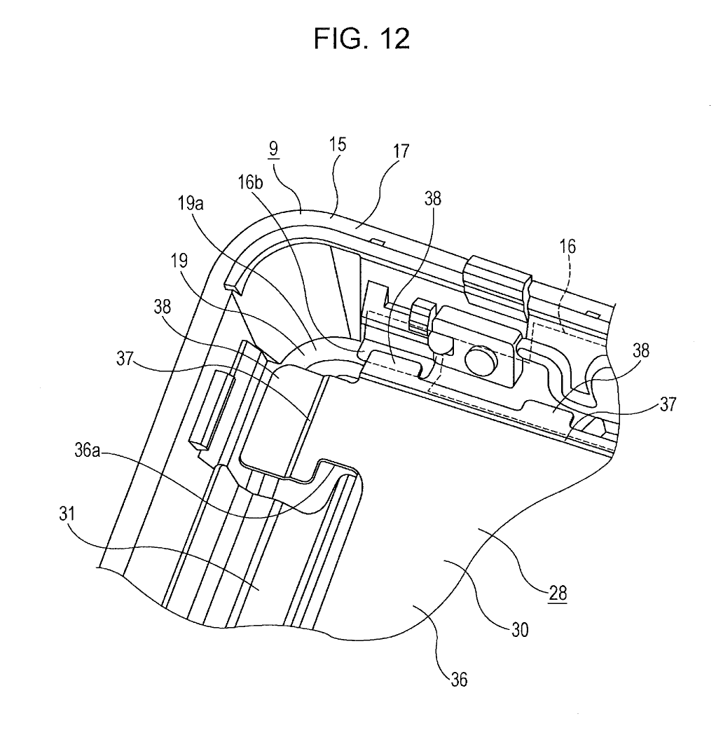

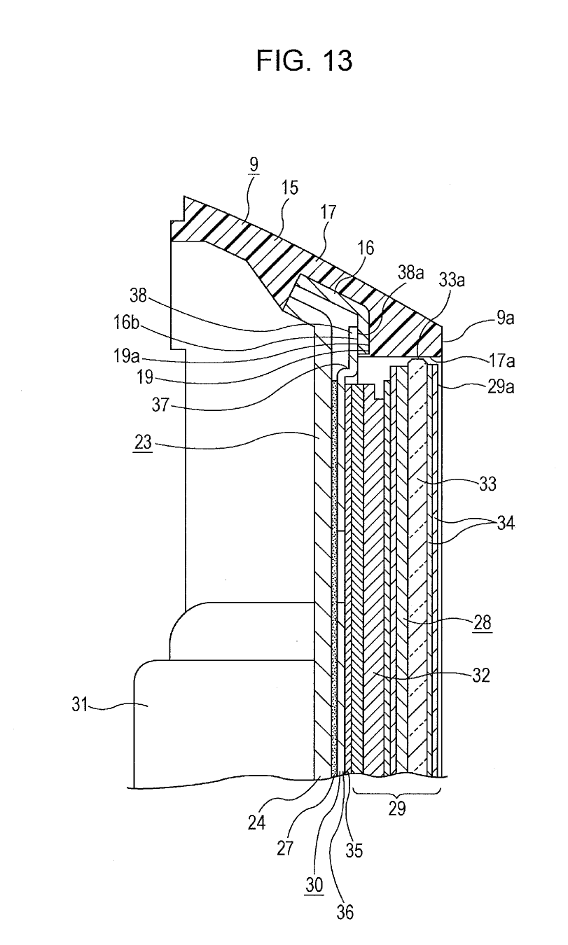

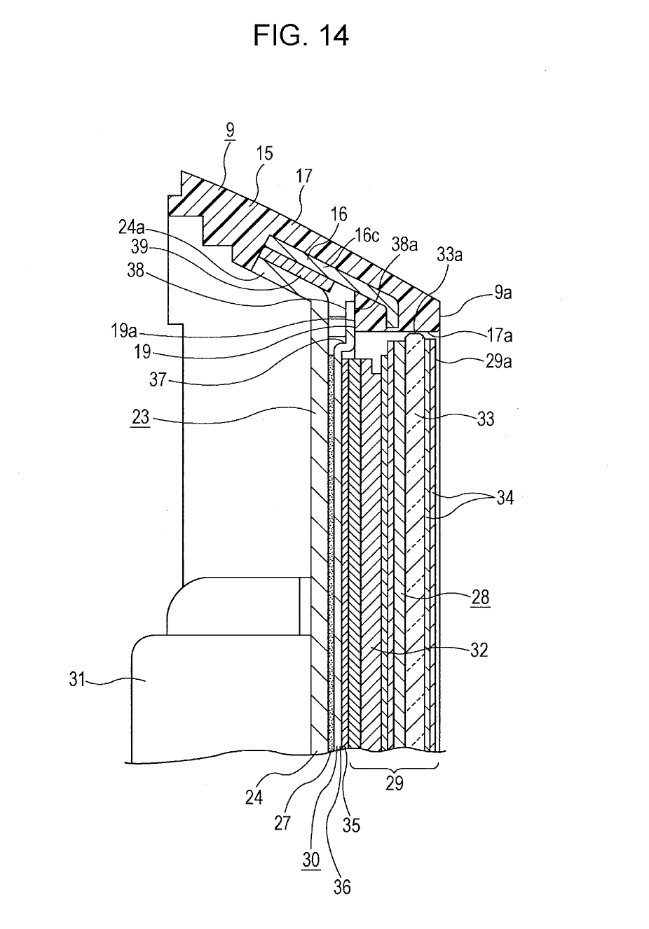

As described above, with the display device 1 implemented, one contact portion 38 of the holding base 30 is connected to the first connecting portion 16b formed at the reinforcing portion 16 of the cabinet 9 (see FIGS. 12 and 13). Further, the connecting surface 24a formed at the holding surface 24 of the pressing member 23 is connected to the second connecting portion 16c formed at the reinforcing portion 16 through a conductive cushion 39 (see FIG. 14).

The holding base 30 is connected to an earthed circuit formed on the circuit board. Therefore, as described above, the contact portion 38 of the holding base 30 is connected to the first connecting portion 16b of the reinforcing portion 16 and the contact surface 24a of the pressing member 23 is connected to the second connecting portion 16c of the reinforcing portion 16, such that the holding base 30 is connected to the earthed circuit through the reinforcing portion 16 and the pressing member 23.

As described above, as the holding base 30 of the display unit 28 is connected to the pressing member 23, which is connected to the earthed circuit, by the reinforcing portion 16, the reinforcing portion 16 functions as a conductive path for the holding base 30 when reinforcing the cabinet 9, such that it is possible to reduce the number of parts and prevent damage by electrostatic discharge of the display unit 28.

### [Circuit Configuration of Display Device]

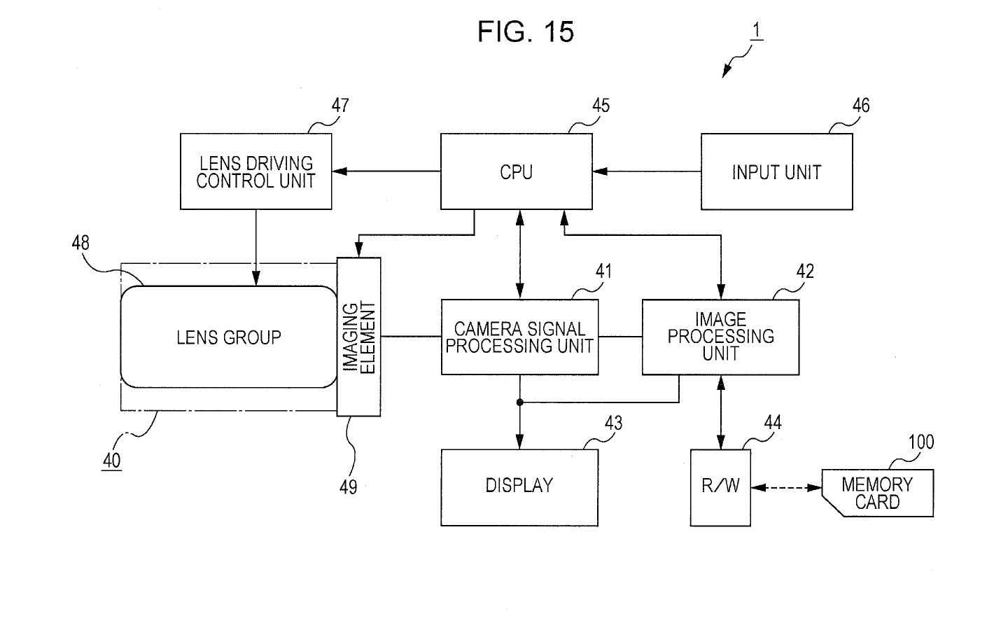

An example of the circuit configuration of the display device (digital still camera) 1 is described hereafter (see FIG. 15).

The display device 1 includes a camera block 40 for imaging, a camera signal processing unit 41 that performs signal processing, such as analog-digital conversion of the signal of an image which is imaged, and an image processing unit 42 that performs recording and reproducing of the image signal. Further, the display device 1 includes a display (display 32) 43 that displays the image which is imaged, an R/W (Reader/Writer) 44 that writes and reads the image data to/from a memory card 100, a CPU (Central Processing Unit) 45 that controls the entire display device 1, an input unit 46 (operation portions 4, 4, . . . ) implemented by various switches for necessary operations from a user, and a lens driving unit 47 that controls driving of the lens disposed in the camera block 40.

The camera block 40 is composed of an optical system including a lens group 48, or an imaging element 49, such as a CCD (Charge Coupled Device) or a CMOS (Complementary Metal-Oxide Semiconductor).

The camera signal processing unit 41 performs various signal processing, such as converting an output signal from the imaging element 49 into a digital signal, removing noise, correcting the image quality, and converting into a luminance•color difference signal.

The image processing unit 42 performs compression coding•extension coding or conversion of data-specification, such as resolution, on the basis of a predetermined image data-format.

The display 43 has a function of showing the operation states of the input unit 46 by the user or various data, such as the image which is imaged.

The R/W 44 writes image data encoded by the image processing unit 42 onto the memory card 100 and reads the image data recorded on the memory car 100.

The CPU 45 functions as a control processing unit that controls the circuit blocks disposed in the display device 1 and controls the circuit blocks on the basis of instruction input signals from the input unit 46.

The input unit 46 outputs the instruction input signal according an operation of the user to the CPU 45.

The lens driving control unit 47 controls a motor or the like (not shown) that drives the lenses in the lens group 48 on the basis of control signals from the CPU 45.

The memory card 100 is a detachable semiconductor memory that is attached to a slot connected tot eh R/W 44, for example.

The operation of the display device 1 is described hereafter.

In an imaging standby state, the signal of an image imaged by the camera block 40 is output to the display 43 through the camera signal processing unit 41 and displayed as a camera-through image under the control of the CPU 45. Further, when a instruction input signal for zooming is input from the input unit 46, the CPU 45 outputs a control signal to the lens driving control unit 47 and a predetermined lens in the lens group 48 is moved on the basis of the control of the lens driving control unit 47.

A shutter (not shown) of the camera block 40 is operated by the instruction input signal from the input unit 46, the signal of the image that is imaged is output to the image processing unit 42 from the camera signal processing unit 41, and then the signal is compression-encoded and converted into digital data having a predetermined data format. The converted data is output to the R/W 44 and written on the memory card 100.

Further, focusing is implemented, for example, when the shutter button of the input unit 46 is half pressed or fully pressed for recording (imaging) and the lens driving control unit 47 moves a predetermined lens in the lens group 48 on the basis of a control signal from the CPU 45.

When the image data recorded on the memory card 100 is reproduced, in accordance with the operation of the input unit 46, predetermined image data is read from the memory card 100 by the R/W 44 and undergoes expansion coding in the image processing unit 42, and then a reproduction image signal is output to the display 43 and a reproduced image is displayed.

### CONCLUSION

As described above, in the display device 1, with the contact portions 38, 38, . . . of the holding base 30 in contact with the receiving portions 19, 19, . . . of the cabinet 9, the holding base 30 is pressed by the pressing member 23 and the display unit 28 is disposed with respect to the cabinet 9.

Further, as the aligning surface 33a of the display unit 29 and the positioning surface 17a of the cabinet 9 are positioned opposite to each other, the display portion 29 is positioned with respect to the cabinet 9.

Therefore, it is possible to ensure high accuracy of positioning the display portion 29 with respect to the cabinet 9 and there is no portion that presses the display portion 29 outside (behind) the display portion 29, such that the display device 1 correspondingly decreases in thickness, and accordingly, it is possible to reduce the size of the display device 1 (decrease the thickness) while ensuring high accuracy of positioning the display portion 29 with respect to the cabinet 9.

Further, since there is no portion closing the outer circumferential portion of the display portion 29, it is possible to correspondingly increase the display region of an image in the display portion 29 and it is also possible to reduce the outer shape of the display device 1, such that it is possible to reduce the size of the display device 1.

Further, since the display portion 29 is disposed in the cabinet 9 without protruding rearward from the cabinet 9, it is possible to further reduce the size of the display device 1.

Further, the display portion 29 is provided with the display 32 and the protective glass 33 that protects the display 32, and the aligning surface 33a of the protective glass 33 and the positioning surface 17a of the cabinet 9 are positioned to opposite to each other.

Therefore, since the display portion 29 is positioned with respect to the cabinet 9 by the protective glass 3 and the glass material that is the material of the protective glass 33 has high machining accuracy and strength, it is possible to highly accurately position the display portion 29 with respect to the cabinet 9.

Further, since the contact portions 38 and 38 of the holding base 30 are disposed at both sides of the connecting substrate 31, the position of the holding base 30 to the cabinet 9 is not easily changed by an external force applied to the connecting substrate 31 and it is possible to stably hold the display unit 28 with the cabinet 9.

Further, in the display device 1, since the pressing member 23 is fixed inside the outer case 2, it is possible to improve stability of the display unit 28 held with respect to the cabinet 9 without changing the position of the pressing member 23 with respect to the outer case 2.

Further, since the holding base 30 of the display unit 28 is pressed by the pressing member 23 through the cushion 27, the holding base 30 is pressed by the pressing member 23, with deviation of the assembled position absorbed by the cushion 27 on the basis of the machining accuracy of the parts in the display device 1.

Therefore, it is possible to stably hold the display unit 28 with the cabinet 9 regardless of the machining accuracy of the parts in the display device 1.

Further, since the holding base 23 is made of a metal material, the strength of the holding base 30 is high the holding base 30 is not easily deformed when being pressed by the pressing member 23, and the display unit 28 can be further stably held by the cabinet 9.

Further, since the outer shape of the protective glass 33 for positioning the display portion 29 with respect to the cabinet 9 is formed slightly smaller than the shape of the positioning surface 17a of the cabinet 9, a small gap P is formed between the aligning surface 33a and the positioning surface 17a (see FIG. 10).

In the display device 1, as described above, the contact surfaces 38a, 38a, . . . of the contact portions 38, 38, . . . are blacked such that the portion inside the gap P is blacked. Therefore, reflection from the contact portions 38, 38, . . . is suppressed when light travels into the gap P, such that it is possible to improve visibility of the image displayed on the display portion 29.

Further, it is difficult to see the internal structure of the gap P, it is possible to improve the design.

The detailed shapes and structures of the parts described in the preferred embodiments of the present disclosure described above are just examples of the details for implementing the present disclosure and the technical range of the present disclosure should not be construed as being limited.

The present disclosure contains subject matter related to that disclosed in Japanese Priority Patent Application JP 2010-293690 filed in the Japan Patent Office on Dec. 28, 2010, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display device comprising:
an outer case that includes a frame-shaped cabinet having receiving portions on the inner circumferential portion thereof such that a portion of the inner circumferential surface functions as a positioning surface;
a display unit that includes a display portion where a display is disposed and a holding base holding the display portion and in which at least a portion of the outer circumferential portion of the holding base functions as a contact portion positioned further outside than the outermost circumferential surface of the display portion and the outermost circumferential surface of the display portion is formed as an aligning surface; and
a pressing member that is disposed inside the outer case and positioned opposite to the display portion with the holding base therebetween,
wherein the holding base is pressed from the opposite side of the receiving portion of the cabinet by the pressing member, with the contact portion of the holding base in contact with the receiving portion of the cabinet such that the display unit is disposed with respect to the cabinet, and
the aligning surface of the display portion and the positioning surface of the cabinet are positioned opposite to each other such that the display portion is positioned with respect to the cabinet.

2. The display device according to claim 1,
wherein the display portion is disposed in the cabinet.

3. The display device according to claim 1,
wherein a protective glass that protects the display is disposed at the display portion, and
the outer circumferential surface of the protective glass functions as the aligning surface.

4. The display device according to claim 1,
wherein a connecting substrate connected to the display portion is disposed at the display unit,
the connecting substrate protrudes from one edge of the holding base, and
the contact portion is disposed at both sides of the connecting substrate at one edge of the holding base.

5. The display device according to claim 1,
wherein the pressing member is fixed inside the outer case.

6. The display device according to claim 5,
wherein the holding base is pressed by the pressing member through the cushion.

7. The display device according to claim 1,
wherein the holding base is made of a metal material.

8. The display device according to claim 1,
wherein the surface that is in contact with the receiving portion in the contact portion of the cabinet may be blacked.

9. The display device according to claim 1,
wherein the cabinet has a base portion made of a resin material and a reinforcing portion made of a metal material to reinforce the base portion.

10. The display device according to claim 9,
wherein the base portion and the reinforcing portion are integrally formed.

11. The display device according to claim 9,
wherein the holding base is made of a conductive material,
the pressing member is made of a conductive material and connected to an earthed circuit, and
a first connecting portion and a second connecting portion in which the holding base and the pressing member are partially connected, respectively, are formed at the reinforcing portion.
